(19) United States
(12) Patent Application Publication
(10) Pub. No.: US 2013/0051907 A1
(43) Pub. Date: Feb. 28, 2013

(54) CONNECTION MECHANISM CAPABLE OF CONNECTING HOUSINGS

(71) Applicants: HE-TAO HAN, Shenzhen City (CN); SONG DENG, Shenzhen City (CN); JUN-HUA TAN, Shenzhen City (CN); WEN-KANG LO, Tu-Cheng (TW); GUANG-YAO LEE, Tu-Cheng (TW)

(72) Inventors: HE-TAO HAN, Shenzhen City (CN); SONG DENG, Shenzhen City (CN); JUN-HUA TAN, Shenzhen City (CN); WEN-KANG LO, Tu-Cheng (TW); GUANG-YAO LEE, Tu-Cheng (TW)

(73) Assignees: HON HAI PRECISION INDUSTRY CO., LTD., Tu-Cheng (TW); HONG FU JIN PRECISION INDUSTRY (SHENZHEN) CO., LTD., Shenzhen City (CN)

(21) Appl. No.: 13/286,164

(22) Filed: Oct. 31, 2011

(30) Foreign Application Priority Data
Aug. 25, 2011 (CN) 201110246231.7

(51) Int. Cl. H05K 5/02

(52) U.S. Cl. 403/322.1

(57) ABSTRACT

A connection mechanism to connect a first housing and a second housing together is provided. The connection mechanism includes a base, a button, and at least one rotatable member. The base includes at least one first hook and is slidably connected to the first housing. The base is capable of sliding between a first position where the first hook engages the second housing, and a second position where the first hook disengages from the second housing. The button is slidably connected to the first housing. The rotatable member is rotatably connected to the first housing, where one end of the rotatable member resists against the button, an opposite end of the rotatable member resists against the base, and the rotatable member is capable of being rotated about a shaft between the one end and the opposite end.

### BACKGROUND

1. Technical Field

The present disclosure relates to connection mechanisms capable of connecting housings together.

2. Description of Related Art

Screws are commonly used to connect two articles together, such as an upper housing and a lower housing of a cell phone. Another way to connect such two housings is using hooks engaging with slots. Although such connection techniques satisfy basic requirements, a new connection mechanism is still required.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a connection mechanism for connecting a first housing and a second housing in accordance with an exemplary embodiment.

FIG. 2 is an exploded view of the connection mechanism that connects the first housing and the second housing of FIG. 1.

FIG. 3 is similar to FIG. 1, with the second housing detached from the first housing.

### DETAILED DESCRIPTION

The disclosure is illustrated by way of example and not by way of limitation.

It should be noted that references to “an” or “one” embodiment in this disclosure are not necessarily to the same embodiment, and such references mean at least one.

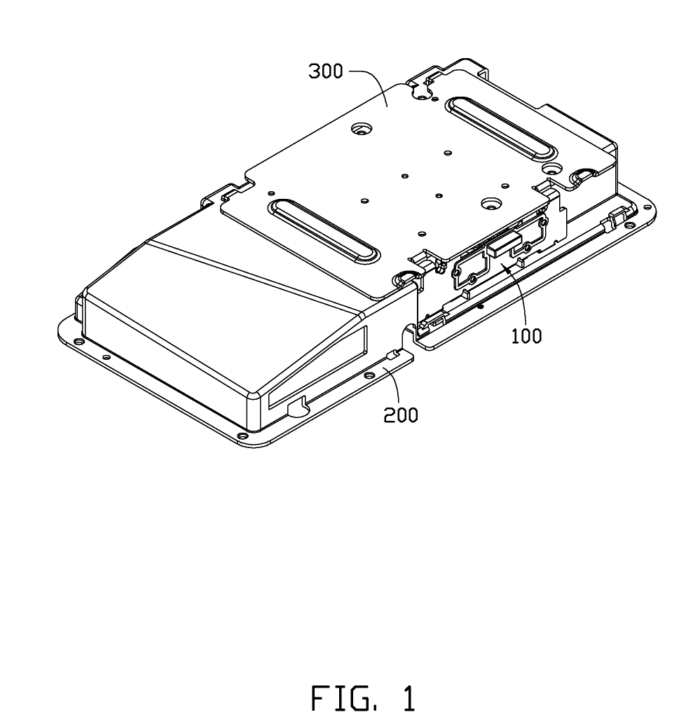

Referring to FIG. 1, a connection mechanism 100 is disclosed to connect at least two housings together. In this embodiment, a first housing 200 and a second housing 300 are illustrated as an example.

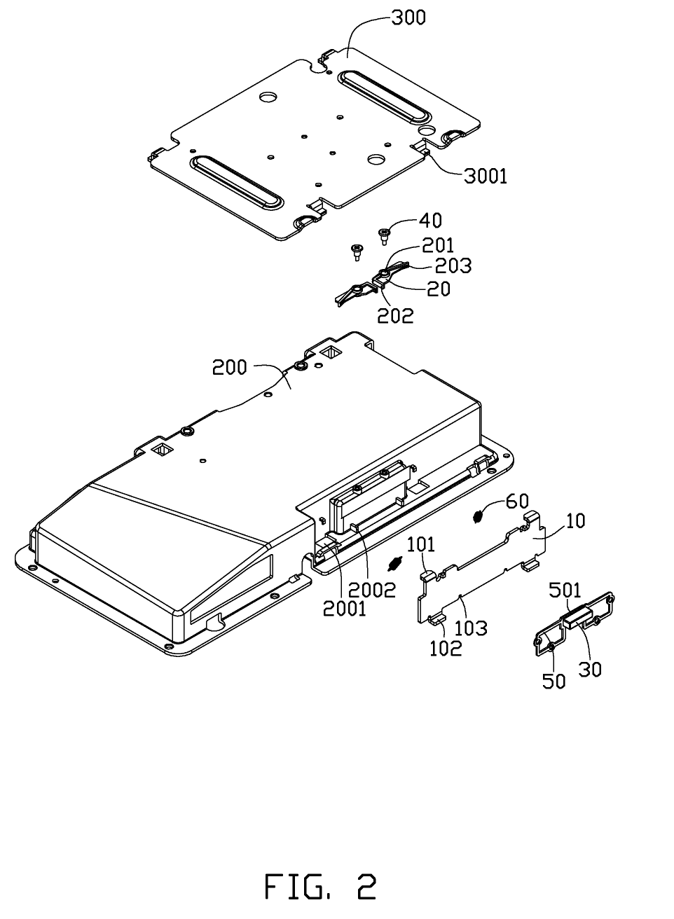

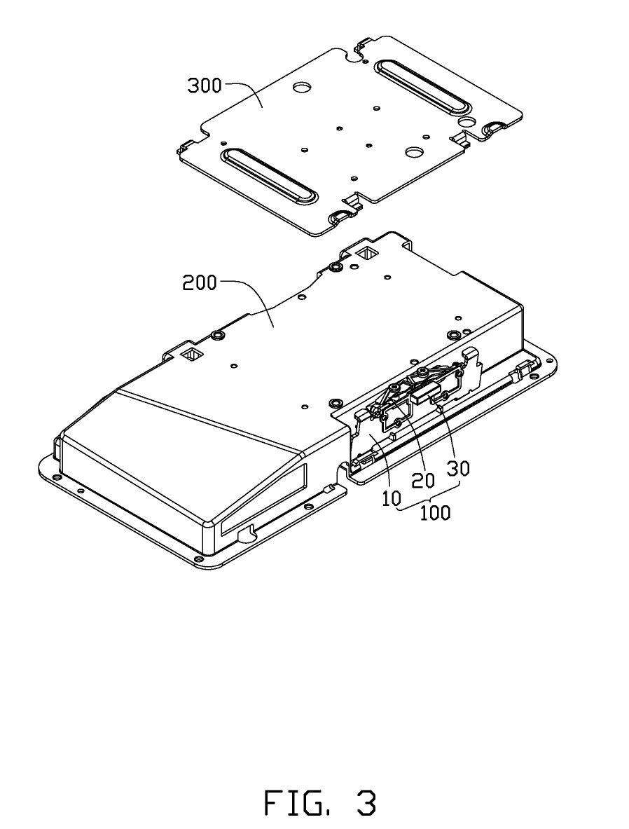

Referring to FIGS. 2-3, the connection mechanism 100 includes a base 10, at least one rotatable member 20, and a button 30. The base 10 is slidably connected to the first housing 200 and includes at least one first hook 101. When the base 10 is in a first position, the at least one hook 101 engages the second housing 300, thereby connecting the first housing 200 and the second housing 300 together. When the base 10 slides from the first position to a second position, the at least one hook 101 disengages from the second housing 300, thereby freeing the second housing 300 from limitation, and the second housing 300 can then be detached from the first housing 200.

In this embodiment, the base 10 is a planar structure and arranged substantially perpendicularly to a bottom surface of the first housing 200. Two first hooks 101 are arranged on the base 10. Two tabs 3001 are arranged on the second housing 300 to respectively engage with the two first hooks 101. The two first hooks 101 protrude from an upper edge of the base 10. The two tabs 3001 extend downward from an edge of the second housing 300.

In this embodiment, the base 10 further includes two second hooks 102. Each second hook 102 is received in a receiving cavity 2001 defined in the first housing 200, allowing the base 10 to be capable of sliding with respect to the first housing 200. The second hooks 102 protrude from a lower edge of the base 10. The first hooks 101 and the second hooks 102 are substantially perpendicular to the base 10. When the base 10 is in the first position, the second hooks 102 are received in the receiving cavities 2001 and the first hooks 101 hook the tabs 3001. When the base 10 slides away from the first housing 200 from the first position to the second position, the first hooks 101 disengage with the tabs 3001. In an alternative embodiment, the number of the first hooks 101, the tabs 3001, the second hooks 102, and the receiving cavities 2001 may be varied according to actual need.

The rotatable member 20 is rotatably connected to the first housing 200. One end 202 of the rotatable member 20 resists against the button 30, an opposite end 203 of the rotatable member 20 resists against the base 10, and the rotatable member is capable of being rotated about a shaft between the one end 202 and the opposite end 203.

In this embodiment, one headed rotating shaft 40 passes through a through hole 201 on each rotatable member 20 and is fixed to the first housing 200, thereby connecting the rotatable member 20 to the first housing 200 and allowing the rotatable member 20 to rotate about the shaft 40.

The button 30 can be depressed to move along a sliding direction of the base 10. When the button 30 is depressed to move toward the first housing 200, the rotatable member 20 is pushed by the button 30 and rotates about the shaft 40, causing the base 10 to slide away from the first housing 200 from the first position to the second position. In this embodiment, the connection mechanism 100 includes two rotatable members 20. Two close ends 202 on the two rotatable members 20 respectively resist against the button 30, and two other ends 203 on the two rotatable members 20 respectively resist against the base 10.

In this embodiment, the connection mechanism 100 further includes a frame 50 arranged on the base 10. The frame 50 defines an opening 501 to receive the button 30. When being pressed, the button 30 is guided by the opening 501 and slides.

In this embodiment, two notches 103 are arranged in the lower edge of the base 10, and two guiding rails 2002 are formed on the first housing 200 and substantially perpendicular to the at least one base 10. The guiding rails 2002 slidably engages the notches 103, allowing the base 10 to slide along the guiding rails 2002.

In this embodiment, the connection mechanism 100 further includes two elastic members 60. One end of each elastic member 60 is fixed to the first housing 200, and the other end of each elastic member 60 is fixed to the base 10. When the button 30 is depressed, the base 10 is pushed to move away from the first housing 200, and the two elastic members 60 are stretched. After the depression is released, the two elastic members 50 rebound and pull the base 10 back to an initial position.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A connection mechanism to connect a first housing and a second housing together, the connection mechanism comprising:
a base slidably connected to the first housing and comprising at least one first hook, wherein the base is slidable between a first position where the at least one first hook engages the second housing, and a second position where the at least one first hook disengages from the second housing;
a button slidably connected to the first housing; and
at least one rotatable member rotatably connected to the first housing, wherein one end of each of the at least one rotatable member resists against the button, an opposite end of each of the at least one rotatable member resists against the base, and each of the at least one rotatable member is capable of being rotated about a shaft between the one end and the opposite end.

2. The connection mechanism as described in claim 1, wherein when the button is depressed to move toward the first housing, each of the at least one rotatable member is pushed by the button and rotates about the shaft, causing the base to slide away from the first housing from the first position to the second position.

3. The connection mechanism as described in claim 2, wherein the base comprises at least one second hook, each second hook is received in a receiving cavity defined in the first housing, allowing the base to be capable of sliding with respect to the first housing.

4. The connection mechanism as described in claim 3, wherein the base is a planar structure and arranged substantially perpendicularly to a bottom surface of the first housing, the at least one first hook and the at least one second hook are substantially perpendicular to the base, the at least one first hook protrudes from an upper edge of the base, and the at least one second hook protrudes from a lower edge of the base.

5. The connection mechanism as described in claim 2, wherein the shaft is a headed rotating shaft passing through a through hole on each rotatable member and being fixed to the first housing.

6. The connection mechanism as described in claim 2, wherein the number of the at least one rotatably member is two, two close ends on the two rotatable members respectively resist against the button, and two opposite ends on the two rotatable members resist against the base.

7. The connection mechanism as described in claim 2 further comprising a frame arranged on the base, and the frame defines an opening to receive the button.

8. The connection mechanism as described in claim 2, wherein at least one notch is arranged in the lower edge of the base, at least one guiding rail is formed on the first housing and substantially perpendicular to the base, and the at least one guiding rail slidably engages the at least one notch, allowing the base to slide along the at least one guiding rail.

9. The connection mechanism as described in claim 2, further comprising at least one elastic member, one end of each of the at least one elastic member is fixed to the first housing, and an opposite end of the elastic member is fixed to the base.
